(19) United States
(12) Patent Application Publication
(10) Pub. No.: US 2007/0012939 A1
(43) Pub. Date: Jan. 18, 2007

(54) Flip chip light emitting diode and method of manufacturing the same

(75) Inventors: Seok Min Hwang, Suwon (KR); Je Won Kim, Suwon (KR); Young Ho Park, Suwon (KR); Kun Yoo Ko, Hwaseong (KR); Jee Youl Kim, Suwon (KR); Jung Kyu Park, Seoul (KR); Bok Ki Min, Cheongju (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/412,984

(22) Filed: Apr. 28, 2006

(30) Foreign Application Priority Data
May 3, 2005 (KR) 10-2005-0036958

(51) Int. Cl. H01L 33/00; H01L 21/00

(52) U.S. Cl. 257/99; 257/778; 438/108; 257/E33.057

(57) ABSTRACT

The present invention relates to a flip chip light emitting diode, in which the flow of current concentrated on a portion adjacent to an n-type electrode can be induced into the center of a light emitting section and a current-spreading effect is accordingly enhanced, thereby increasing light emission efficiency of a light emitting diode chip, and a method of manufacturing the same. The method of manufacturing a flip chip light emitting diode includes sequentially forming an n-type nitride semiconductor layer, an active layer, and a p-type nitride semiconductor layer on an optically-transparent substrate; etching predetermined regions of the active layer and p-type nitride semiconductor layer and exposing a plurality of regions of the n-type nitride semiconductor layer so as to form a plurality of mesas; etching predetermined regions of the active layer and p-type nitride semiconductor layer positioned between the formed mesas and exposing the plurality of regions of the n-type nitride semiconductor layer so as to form a plurality of grooves; forming an insulating layer on the surface of the groove; forming a p-type electrode across the insulating layer formed on the upper portion of the p-type nitride semiconductor layer and the surface of the groove; and forming an n-type electrode on the formed mesa.

### CROSS-REFERENCE TO RELATED APPLICATIONS

The application claims the benefit of Korea Patent Application No. 2005-0036958 filed with the Korea Industrial Property Office on May 3, 2005, the disclosure of which is incorporated herein by reference.

### BACKGROUND OF THE INVENTION

1. Field of the Invention

The present invention relates to a flip chip light emitting diode and a method of manufacturing the same, and more specifically, to a flip chip light emitting diode in which a plurality of mesas for forming an n-type electrode are formed, a plurality of grooves are formed by etching predetermined regions between the mesas, and a large amount of current is accordingly caused to flow into the center of a light emitting section to thereby obtain a current-spreading effect, and a method of manufacturing the same.

2. Description of the Related Art

In general, a light emitting diode (LED) is such an element that converts an electrical signal into the form of infrared rays, ultraviolet rays or light so as to send and receive signals by using the characteristics of a compound semiconductor such as the recombining of electrons and holes.

A light emitting diode is generally used in home appliances, remote controls, electronic display boards, markers, automation equipments, optical communication devices, and the like. The light emitting diode is roughly divided into an IRED (infrared emitting diode) and VLED (visible light emitting diode).

In a light emitting diode, the frequency (or wavelength) of emitted light is utilized as a band-gap function of a material used in the semiconductor device. When a semiconductor material having a small band gap is used, a photon having low energy and a long wavelength is generated. When a semiconductor material having a large band gap is used, a photon having a short wavelength is generated. Accordingly, a semiconductor material is selected according to the type of light which is desired to be emitted.

In the case of a red light emitting diode, a material such as AlGaInP is used. In the case of a blue light emitting diode, silicon carbide (SiC) and gallium nitride (GaN) as a nitride semiconductor of the group III are used. Recently, as a nitride semiconductor used in a blue light emitting diode, (AlₓIn₁₋ₓ)_{y}Ga_{1-y}N (0<x<1 and 0<y<1) has been widely used.

Among them, since bulk single-crystal GaN cannot be formed in a gallium-base light emitting diode, a substrate suitable for the growth of GaN crystal should be used. Sapphire is representatively used.

FIG. 1 is a cross-sectional view illustrating a GaN light emitting diode according to the related art. The GaN light emitting diode 9 includes a sapphire growth substrate 1, a light emitting structure 8 formed on the sapphire growth substrate 1, a p-type electrode 6 formed on the light emitting structure 8, and an n-type electrode 7.

In the GaN light emitting structure 8, a p-type nitride semiconductor layer 4 and an active layer 3 are mesa-etched to expose a portion of the upper surface of an n-type nitride semiconductor layer 2. On the exposed upper surface of the n-type nitride semiconductor layer 2 and the unetched upper surface of the p-type nitride semiconductor layer 4, a p-type electrode 6 and an n-type electrode 7 are respectively formed so as to apply a predetermined voltage. In general, in order not to have a bad influence on the brightness of light generated while increasing a current injection area, a transparent electrode 5 can be formed on the upper surface of the p-type nitride semiconductor layer 4 before the p-type electrode 6 is formed.

In the GaN-based light emitting diode having such a construction, a light emitting diode package can be manufactured through a die bonding process by a chip-side-up method. In this case, light emits in the direction where the p-type electrode 6 and the n-type electrode 7 are formed. In the portion where the electrodes 6 and 7 are formed, light cannot be emitted. Further, the radiation of heat generated in a chip when light is emitted is reduced due to low heat conductivity of sapphire, thereby reducing the lifetime of the light emitting diode.

In order to solve the problems, the GaN-based light emitting diode can be constructed in the form of a flip chip in which the light emitting diode 9 of FIG. 1 is turned upside down and the p-type electrode 6 and the n-type electrode 7 are directly mounted on a printed circuit board or lead frame through a die bonding process so that the direction of light emission is set to the direction where the sapphire substrate 1 is formed.

In such a flip chip light emitting diode, predetermined regions of the grown active layer and p-type nitride semiconductor layer are etched to expose a plurality of regions of the n-type nitride semiconductor layer, in order to form more than one n-type electrode. In this case, the exposed portion is referred to as a mesa. On the mesa, the n-type electrode and insulating body are formed to thereby manufacture a light emitting diode chip.

FIGS. 2A and 2B are diagrams showing a state where a light emitting diode according to the related art is flip-chip bonded.

FIG. 2A illustrate a silicon submount 20 to which the manufactured light emitting diode chip is joined. Reference numerals 21 and 22 represent positions where solder bumps are attached in order to electrically join the p-type and n-type electrodes of the manufactured light emitting diode to the electrodes of the silicon submount 20.

FIG. 2B illustrates the light emitting diode according to the related art which is flip-chip bonded. As shown in FIG. 2B, the light emitting diode is composed of a sapphire substrate 1, a light emitting structure 8 which is formed by sequentially laminating an n-type nitride semiconductor layer, an active layer, and a p-type nitride semiconductor layer on the sapphire substrate 1, a p-type electrode 6 which is formed by sequentially laminating p-type ohmic metal, barrier metal, and bonding metal on a predetermined position of the upper portion of the light emitting structure 8, and an n-type electrode 7 which is formed on a predetermined region of the n-type nitride semiconductor layer so as to be used for bonding or applying a voltage. Such a light emitting diode is directly joined to the silicon submount 20 with the solder bumps 10 interposed therebetween, the solder bumps 10 being formed on the p-type electrode 6 and the n-type electrode 7. At this time, the p-type electrode 6 and the n-type electrode 7 are respectively connected to an anode 11 and cathode 12 formed on the silicon submount 20 through the solder bumps 10.

In the above-described flip chip light emitting diode according to the related art, however, the length of the current path increases as the current path is gradually distant from the n-type electrode. Then, the resistance of N—GaN increases. As a result, electric current is concentrated and flows in a portion adjacent to the n-type electrode, thereby reducing a current-spreading effect.

### SUMMARY OF THE INVENTION

An advantage of the present invention is that it provides a flip chip light emitting diode in which an active layer and a p-type nitride semiconductor layer are etched so that an n-type nitride semiconductor layer in a light emitting structure positioned between mesas is exposed to form a plurality of grooves and an insulating layer is formed on the surface of the groove so as to induce the flow of current to the center portion, thereby improving the light emission efficiency of the center portion of a light emitting diode chip, and a method of manufacturing the same.

Another advantage of the invention is that it provides a flip chip light emitting diode in which, when the plurality of grooves are formed, intervals between the grooves are designed to change so that a large amount of current, which has been concentrated toward an n-type electrode in the related art, can flow into the center of a light emitting section, thereby obtaining a current spreading effect, and a method of manufacturing the same.

Additional aspects and advantages of the present general inventive concept will be set forth in part in the description which follows and, in part, will be obvious from the description, or may be learned by practice of the general inventive concept.

According to an aspect of the invention, a method of manufacturing a flip chip light emitting diode includes sequentially forming an n-type nitride semiconductor layer, an active layer, and a p-type nitride semiconductor layer on an optically-transparent substrate; etching predetermined regions of the active layer and p-type nitride semiconductor layer and exposing a plurality of regions of the n-type nitride semiconductor layer so as to form a plurality of mesas; etching predetermined regions of the active layer and p-type nitride semiconductor layer positioned between the formed mesas and exposing the plurality of regions of the n-type nitride semiconductor layer so as to form a plurality of grooves; forming an insulating layer on the surface of the groove; forming a p-type electrode across the insulating layer formed on the upper portion of the p-type nitride semiconductor layer and the surface of the groove; and forming an n-type electrode on the formed mesa.

In forming the mesas or forming the grooves, etching is performed by an RIE method.

In forming the mesas or forming the grooves, the predetermined regions of the active layer and p-type nitride semiconductor layer are etched.

In forming the grooves, etching is performed so that the width of the groove corresponds to the range of 1 to 50 μm.

In forming the grooves, etching is performed so that intervals between the plurality of grooves are reduced as the intervals approach the mesa.

In forming the grooves, etching is performed so that an angle between the bottom and side surfaces of the groove is in the range of 90° to 165°.

In forming the p-type electrode, p-type ohmic metal, barrier metal, and bonding metal are sequentially laminated.

In forming the n-type electrode, n-type ohmic metal is laminated.

According to another aspect of the invention, a flip chip light emitting diode includes an optically-transparent substrate; a light emitting structure that is formed by sequentially forming an n-type nitride semiconductor layer, an active layer, and a p-type nitride semiconductor layer on the substrate, the light emitting structure including: a plurality of mesas that are formed by exposing a plurality of regions of the n-type nitride semiconductor layer so that the regions have a predetermined width; and a plurality of grooves that are formed by exposing a plurality of regions of the n-type nitride semiconductor layer positioned between the mesas so that the regions have a predetermined width; a groove insulating layer that is formed across the surface of the groove of the light emitting structure; a p-type electrode that is formed across the insulting layer formed on the upper portion of the p-type nitride semiconductor layer and the surface of the groove in the light emitting structure; and an n-type electrode that is formed on the plurality of mesas of the light emitting structure.

The light emitting structure is formed by the reactive ion etching (RIE) of the active layer and p-type nitride semiconductor layer.

The width of the groove positioned in the light emitting structure is in the range of 1 to 50 μm.

The plurality of grooves formed in the light emitting structure are formed so that the intervals between the grooves are reduced as the intervals approach the mesa on which the n-type electrode is formed.

The plurality of grooves formed in the light emitting structure are formed so that an angle between the bottom and side surfaces of the groove is in the range of 90° to 165°.

The p-type electrode is formed by sequentially laminating p-type ohmic metal, barrier metal, and bonding metal.

The n-type electrode is formed by laminating n-type ohmic metal.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view illustrating a light emitting diode according to the related art;

FIGS. 2A and 2B are diagrams showing a state where the light emitting diode according to the related art is flip-chip bonded;

FIG. 3 is a cross-sectional view illustrating a flip chip light emitting diode according to an embodiment of the present invention;

FIGS. 4A to 4D are enlarged cross-sectional views illustrating a groove insulating layer formed across the groove and the surface of the groove shown in FIG. 3 and a p-type electrode formed on the groove insulating layer;

FIG. 5 is a plan view illustrating the flip chip diode according to an embodiment of the invention;

FIG. 6 is a plan view illustrating a modified example of the flip chip light emitting diode according to the invention;

FIG. 7 is a plan view illustrating a modified example of the flip chip light emitting diode according to the invention;

FIG. 8 is a flow chart showing a method of manufacturing the flip chip light emitting diode according to the invention;

FIGS. 9A to 9F are cross-sectional views illustrating a manufacturing process of the flip chip light emitting diode according to the invention.

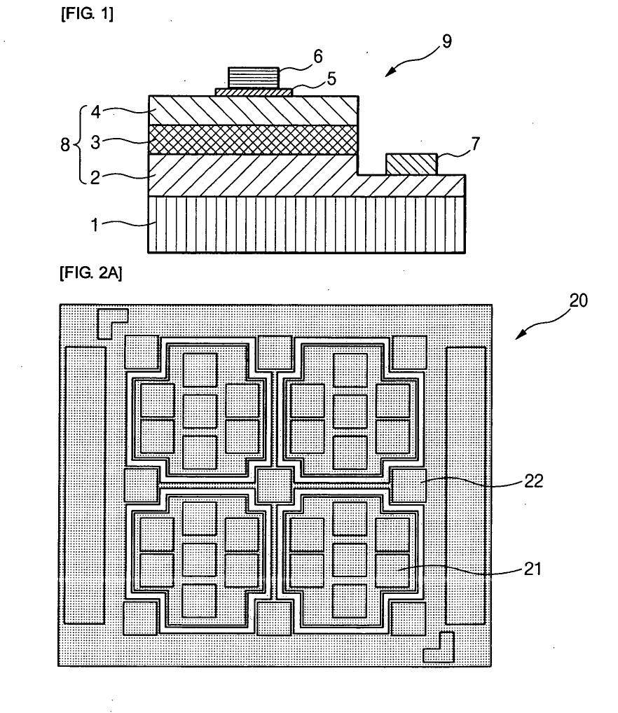

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

Hereinafter, a preferred embodiment of the present invention will be described in detail with reference to the accompanying drawings.

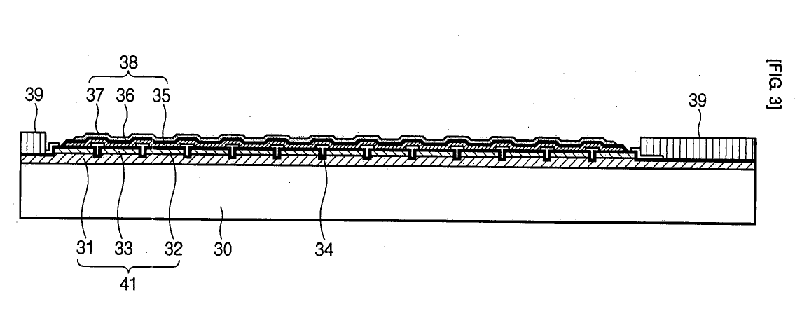

FIG. 3 illustrates the cross-sectional construction of a flip chip light emitting diode according to an embodiment of the invention. As shown in FIG. 3, the flip chip light emitting diode according to an embodiment of the invention includes a sapphire substrate 30 which is an optically-transparent substrate and a light emitting structure 40 which is formed by sequentially laminating an n-type nitride semiconductor layer 31, an active layer 32 having a multi-quantum well structure, and a p-type nitride semiconductor layer 33. The light emitting structure 41 includes a plurality of mesas (not shown) which are formed by etching the p-type nitride semiconductor layer 33 and the active layer 32 and exposing a portion of the upper surface of the n-type nitride semiconductor layer 31 and a plurality of grooves (not shown) which are formed by etching predetermined regions of the active layer and p-type nitride semiconductor layer of the light emitting structure 41 positioned between the plurality of mesas and exposing a plurality of regions of the n-type nitride semiconductor layer. Further, on the surface of the groove, a groove insulating layer 34 is formed. Across the surfaces of the p-type nitride semiconductor layer 33 and groove insulating layer 34, a p-type electrode 38 is formed, in which p-type ohmic metal 35, barrier metal 36, and bonding metal 37 are sequentially laminated.

The light emitting structure 44, which is formed by sequentially laminating the n-type nitride semiconductor layer 31, the active layer 32, and the p-type nitride semiconductor layer 33 on the sapphire substrate 30 used as an optically-transparent substrate, can be manufactured by using a MOCVD (metal organic chemical vapor deposition) method or the like. In the MOCVD method, a material composed of a volatile alkyl compound which is an organic metal compound of the group III and a hydrogen compound of the group V is vapor-thermally decomposed into a III-V group compound. Such a method is preferably used in manufacturing a high-brightness light emitting diode, because a very thin growth layer corresponding to the MBE level can be grown and a thin film with good quality can be reproduced and mass-produced, even though the used material is poisonous and explosive. At this time, before the n-type nitride semiconductor layer 31 is grown, a buffer layer (not shown) composed of AIN/GaN can be formed, in order to improve the lattice matching with the sapphire substrate 30.

In general, the active layer 32 has such structures as a double hetero structure and a single or multi quantum well structure. In the double hetero structure, the active layers 32 of a light emitting region are grown to have a thickness of 10 to 100 nm, and a donor and acceptor are co-doped so that the active layers are radiatively recombined from the donor-acceptor pair (DAP). In the single or multi quantum well structure, light emitting layers are manufactured with a thickness of 1 to 10 nm so as to form a quantum well structure and thus are radiatively recombined through the band-to-band transition. It is preferable to manufacture a thin light emitting diode having a quantum structure in which the thickness of the active layer 32 does not exceed a pseudomorphic critical layer thickness where an electric potential is not generated due to dislocation caused by the lattice mismatch between respective semiconductor thin layers.

The mesa formed in the light emitting structure 41 is formed as follows: the active layer 32 and the p-type nitride semiconductor layer 33 are grown across the overall portion of the n-type nitride semiconductor layer 31, and predetermined regions of the grown active layer 32 and p-type nitride semiconductor layer 33 are etched. In the mesa formed in such a manner, the n-type electrode 39 is positioned. Further, predetermined regions of the active layers and p-type nitride semiconductor layers positioned between the mesas are etched to thereby form the plurality of grooves.

As an etching method when the mesas and grooves are formed, an RIE method is preferably used. In the RIE method, the mesa and groove can be accurately etched to have a desired shape, compared with a wet etching method. Further, an angle with respect to the cross-section of the mesa and groove, which will be described below, can be easily adjusted to thereby improve light emission efficiency.

On the other hand, a portion of an insulating body as well as the n-type electrode can be formed on the mesa, the insulating body protecting a light emitting diode. In this case, the mesa needs to have a width of 25 to 50 μm, because the width of the n-type electrode corresponds to 15 to 30 μm and the width of the portion of the insulating body corresponds to 10 to 20 μm.

On each surface of the plurality of grooves formed in the light emitting structure 41, the groove insulating layer 34 is formed, by which the flow of current concentrated on a portion close to the n-type electrode 39 can be dispersed into the center portion thereof which is distant from the n-type electrode 39. Preferably, the groove insulating layer 34 can be formed of SiO₂. In addition to that, an insulating material such as Si₃N₄, Al₂O₃, or the like can be used.

The p-type electrode 38 includes the p-type ohmic metal 35, the barrier metal 36, and the bonding metal 37, which are sequentially laminated across the upper surface of the p-type nitride semiconductor layer 33 and the insulating layer 34 formed on the groove.

The p-type ohmic metal 35 is formed of a material selected from a group composed of Pt, Rh, Pd/Ni/Al/Ti/Au, Ni—La solid solution/Au, Pd/Au, Ti/Pt/Au, Pd/Ni, Zn—Ni solid solution/Au, InGaN, Ni/Pd/Au, Ni—La solid solution/Au, Pd/Au, Ti/Pt/Au, Pd/Ni, Pt/Ni/Au, Ta/Ti, Ru/Ni, and Au/Ni/Au.

The barrier metal 36 is laminated, in order to prevent metal for ohmic contact and the uppermost metal layer for wiring from being alloyed. The barrier metal 36 can be typically formed of an alloy of Cr/Ni or Ti and W.

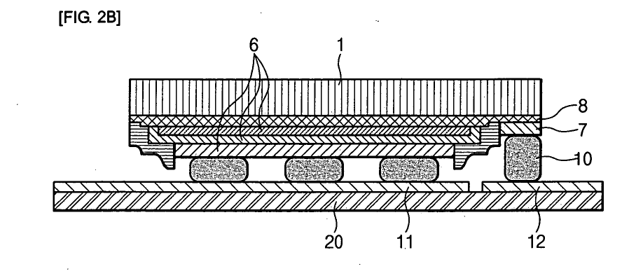

The bonding metal 37 is bonded to an electrode formed on a silicon submount (refer to FIG. 2A) of which the thermal expansion coefficient is similar to that of the sapphire substrate 30. The bonding metal 37 is typically formed of Cr/Au.

On the other hand, the n-type electrode 39 formed on the mesa which is formed by mesa-etching has the n-type ohmic metal laminated therein. The n-type ohmic metal is formed of a material selected from a group composed of Ti/Ag, Ti/Al, Pd/Al, Ni/Au, Si/Ti, ITO, Ti/Al/Pt/Au, ITO/ZnO, Ti/Al/Ni/Au, and Al.

The upper portions of the p-type electrode 38 and n-type electrode 39 are protected by an insulating body composed of a transparent nonconductor film. In this case, a portion of the insulating body is etched so that portions or the overall electrodes 38 and 39 are exposed. In other words, the insulating body is etched in the substantially same form (where the insulating body has the substantially same width and length as those of the electrodes) as the electrodes in the position corresponding to the formed electrodes 38 and 39.

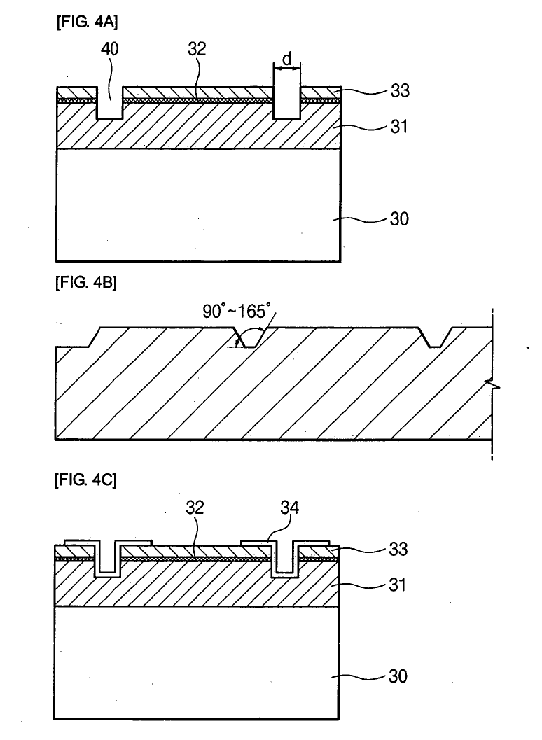

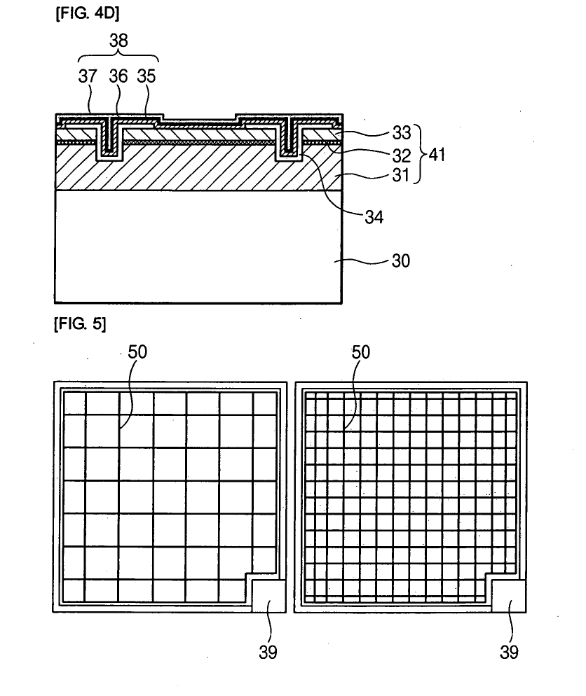

FIGS. 4A to 4B are enlarged cross-sectional views illustrating the groove insulating layer formed across the groove and the surface of the groove shown in FIG. 3 and the p-type electrode formed on the groove insulating layer. Referring to the respective drawings, the groove insulating layer and the p-type electrode will be described in detail.

FIG. 4A illustrates the plurality of grooves 40 which are formed by etching predetermined regions of the grown active layer 32 and p-type nitride semiconductor layer 33, which are positioned between the mesas, and exposing a plurality of regions of the n-type nitride semiconductor layer 31.

The groove 40 is etched so that the width d of the groove 40 corresponds to the range of 1 to 50 μm. If the groove 40 is etched so that the width d of the groove 40 is larger than 50 μm, a portion of the entire light emitting area, occupied by the groove 40 which does not contribute to the light emission, becomes so wide that the light emission efficiency is reduced. Therefore, it is preferable that the width d of the groove 40 should be less than 50 μm.

As shown in FIG. 4B, the groove 40 is etched by using the RIE so that an angle between the bottom and side surfaces of the groove 40 is in the range of 90° to 165°. In general, since a semiconductor composing a light emitting diode has a higher refractive index than an external environment (epoxy or an air layer), most of photons generated by the combining of electrons and holes stay inside the device. Such photons pass through a thin film, a substrate, an electrode, and the like before escaping outside. In this case, some of the photons are absorbed to thereby reduce the external quantum efficiency. In other words, the external quantum efficiency of the light emitting diode is significantly influenced by the constructional shape of the light emitting diode and the optical characteristics of the material composing the light emitting diode. Different from a light emitting diode according to the related art, the external quantum efficiency can be increased in the present invention, because the plurality of grooves 40 are formed by the RIE method so that the light which has been totally reflected and reabsorbed inside is discharged through the groove 40. Particularly, when a light emitting diode is etched so that the angle between the bottom and side surfaces of the groove 40 is adjusted to be oblique, the external quantum efficiency thereof is improved. In general, when the angle between the bottom and side surfaces of the groove 40 is in the range of 150° to 165°, the light emission efficiency is optimal.

FIG. 4C illustrates the groove insulating layer 34 formed on the surface of the etched groove. The groove insulating layer 34 blocks the flow of current passing through the groove so as to induce the flow of current to the center of a light emitting section and to form the p-type electrode on the groove insulating layer 34. Further, the groove insulating layer 34 can be formed in various shapes.

FIG. 4D illustrates the p-type electrode 38 in which the p-type ohmic metal 35, the barrier metal 36, and the bonding metal 37 are sequentially laminated across the surfaces of the p-type nitride semiconductor 33 and the insulating layer 34. As described above, the bonding metal 36 is bonded to the silicon submount (refer to FIG. 2A) having an electrode formed therein. The bonding is typically performed by the solder bumping. In addition to that, the stud bump or eutectic bonding can be also used.

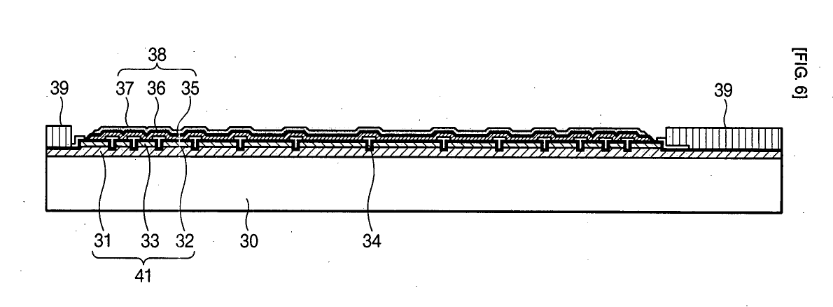

FIG. 5 is a plan view illustrating an embodiment of the flip chip light emitting diode described in FIG. 3. The patterns 50 of the above-described grooves are shown with a straight line. In the portion indicated by the straight line, the groove insulating layer is formed. Further, across the surfaces of the p-type nitride semiconductor layer and the groove insulating layer, the p-type ohmic metal, the barrier metal, and the bonding metal are sequentially laminated to form the p-type electrode.

FIG. 6 is a cross-sectional view illustrating a modified example of the flip chip light emitting diode described in FIG. 3. As shown in FIG. 6, intervals between the grooves are designed to be gradually narrowed as they approach the n-type electrode 39. Accordingly, the cross-sectional area of a current path in a portion adjacent to the n-type electrode 39 can be reduced to thereby improve a current-spreading effect.

In a general flip chip light emitting diode, the resistance of the n-type nitride semiconductor layer 31 increases as it becomes distant from the n-type electrode 39, so that electric current is concentrated and flows in a portion adjacent to the n-type electrode 39. As in the embodiment of the invention, when the intervals between the grooves formed of an insulating body are gradually narrowed as they approach the n-type electrode 39, the cross-sectional area of the current path in a portion adjacent to the n-type electrode 39 is reduced due to the groove insulating layer 34, and the resistance of the portion adjacent to the n-type electrode 39 is increased due to a resistance effect. Accordingly, the overall resistance of the light emitting section becomes averagely constant. Therefore, electric current spreads and flows into the overall light emitting section, thereby obtaining the current-spreading effect. The resistance effect can be defined by the following equation:

R=ρl/S(R: resistance [Ω], ρ: specific resistance[Ωcm], l: length [m], S: cross-sectional area [m²]). Since the cross-sectional area of the current path is reduced, the resistance of the portion adjacent to the n-type electrode 39 is increased by the above equation.

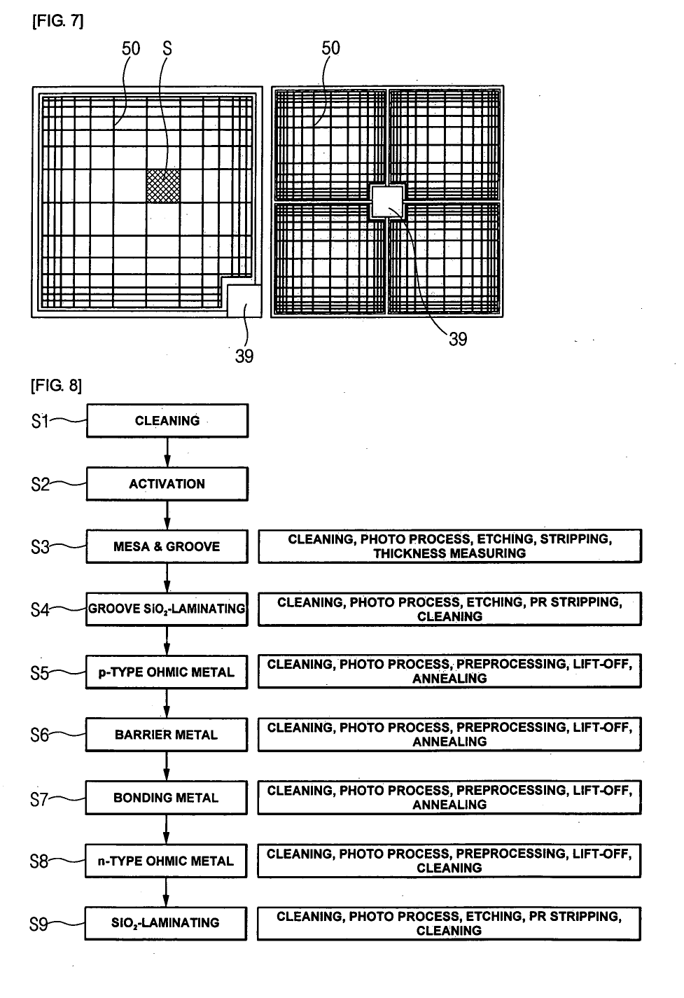

FIG. 7 is a plan view illustrating a modified example of the flip chip light emitting diode described in FIG. 5. As shown in FIG. 7, the areas S of shown rectangles are widened as they become distant from the n-type electrode 39. In other words, if the intervals between the patterns 50 are designed to be gradually narrowed as they approach the n-type electrode 39, the cross-sectional area of the current path of the portion adjacent to the n-type electrode 39 can be reduced, so that a large amount of current flows in the center portion. Accordingly, the current-spreading effect can be obtained.

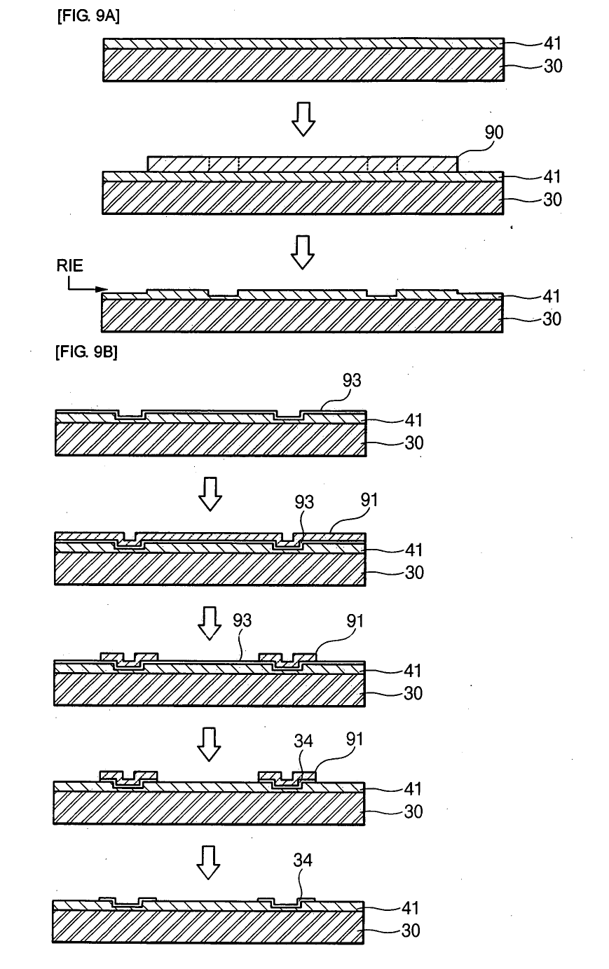

FIG. 8 is a flow chart showing a method of manufacturing the flip chip light emitting diode according to the present invention.

As shown in FIG. 8, the manufacturing method of the flip chip light emitting diode according to the invention can be divided into nine processes.

That is, the manufacturing method includes a cleaning process (S1) in which contaminants on a wafer are removed, an activation process (S2) in which cathodic treatment for discharging or increasing electrons is performed and P—GaN, the n-type nitride semiconductor layer, and the active layer are grown, a forming process (S3) in which the mesas and grooves are formed, a forming process (S4) in which the insulating layer is formed on the surface of the formed groove, forming processes (S5 to S7) in which the p-type electrode is formed across the upper portion of the p-type nitride semiconductor layer and the insulating layer formed on the surface of the groove, that is, in which the p-type ohmic metal is formed, the barrier metal is formed on the p-type ohmic metal, and the boding metal is formed on the barrier metal, a forming process (S8) in which the n-type electrode is formed on the mesa, that is, the n-type ohmic metal is formed, an etching process (S9) in which, after the upper portions of the p-type and n-type nitride semiconductor layers in which the p-type and n-type electrodes are formed are insulated, etching is performed so that predetermined regions of the p-type and n-type electrodes are exposed. Through the manufacturing method, a light emitting diode chip according to the present invention is completed.

The mesas and grooves are formed through a cleaning process, a photo process, an etching process, a stripping process, and a thickness adjusting process. The p-type ohmic metal, the n-type ohmic metal, the barrier metal, and the bonding metal are formed through a cleaning process, a photo process, preprocessing, a lift-off process, and an annealing process. The groove insulating layer and the insulating layer are formed through a cleaning process, a photo process, an etching process, a stripping process, and a cleaning process.

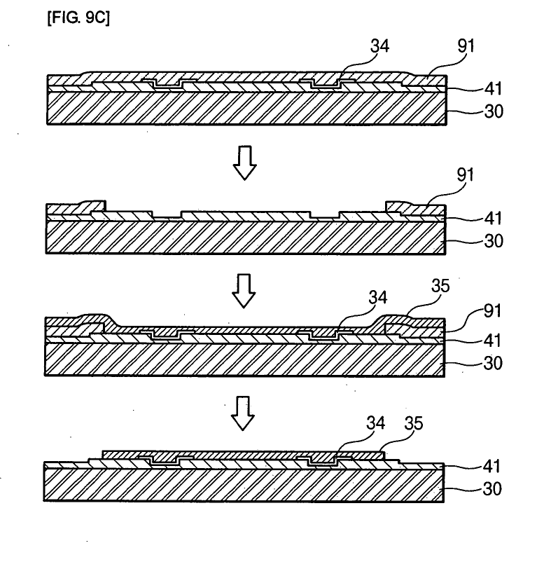

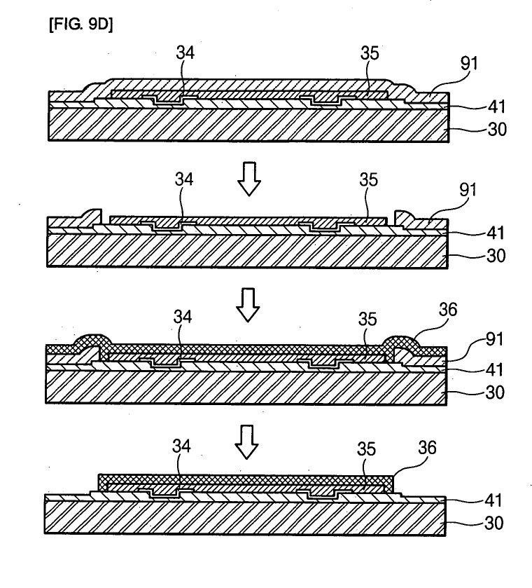

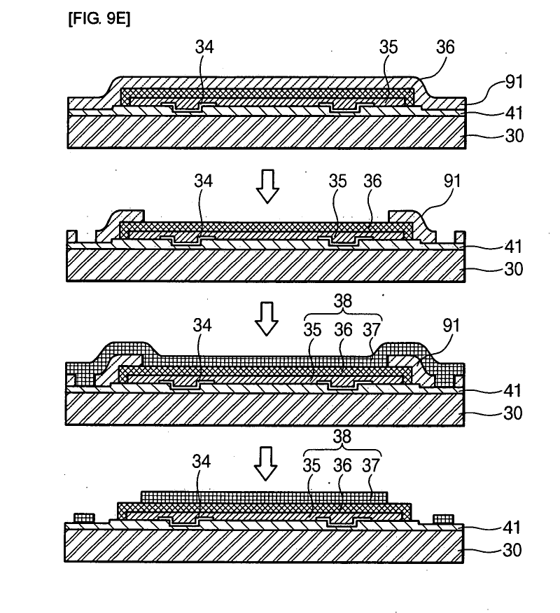

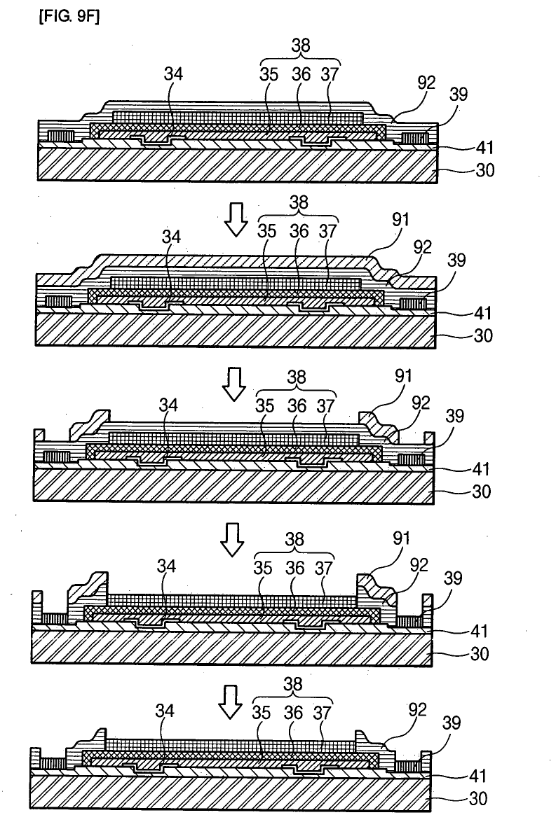

FIGS. 9A to 9F are cross-sectional views showing a manufacturing process of the flip chip light emitting diode according to the invention. The above-described processes will be described in detail with reference to the drawings.

FIG. 9A shows a process of forming the mesas and grooves. Positive photoresist 90 is coated on the light emitting structure 41 and is then etched by using the RIE method, thereby forming the mesas and grooves. At this time, etching can be performed while the widths of the mesas and grooves are adjusted.

FIG. 9B shows a process of forming the groove insulating layer. On the light emitting structure 41 and the surface of the groove, the insulating layer 93 composed of a transparent nonconductor film is formed, and negative photoresist 91 is coated. After the negative photoresist 91 is developed, a portion of the insulating layer 93 is etched so that the light emitting structure 41 is exposed except for the surface of the groove. After that, the negative photoresist 91 which is present on the surface of the groove is removed to thereby form the groove insulating layer 34. The developing process is to remove a predetermined portion of photoresist by using a developing solution, in order to form an image while necessary and unnecessary portions thereof are discriminated.

FIG. 9C shows a process of forming the p-type ohmic metal. On the light emitting structure 41 and the groove insulating layer 34, the negative photoresist 91 is coated. After the negative photoresist 91 is developed, the p-type ohmic metal 35 is laminated. The p-type ohmic metal 35 is formed through a lift-off method. The lift-off method is where photoresist is coated, a crystal portion irradiated with spot-shaped ultraviolet rays is developed, the photoresist is removed, and a light shielding film such as chrome is then deposited so that the photoresist and a non-crystal portion of chrome are removed.

The n-type ohmic metal is formed the same as the p-type ohmic metal is formed (not shown).

FIG. 9D shows a process of forming the barrier metal. On the p-type ohmic metal 35 formed on the light emitting structure 41 and the groove insulating layer 34, the negative photoresist 91 is coated. After the negative photoresist 91 is developed, the barrier metal 36 is laminated. The barrier metal 36 is formed through the lift-off method.

FIG. 9E shows a process of forming the bonding metal. As in the processes of forming the p-type ohmic metal and the barrier metal in FIGS. 9C and 9D, the negative photoresist 91 is coated on the barrier metal 36 formed on the light emitting structure 41 and the groove insulating layer 34. After the negative photoresist 91 is developed, the bonding metal 37 is laminated. The bonding metal 37 is formed through the lift-off method.

FIG. 9F shows a process of forming the insulating layer. On the p-type electrode 38 formed on the light emitting structure 41 and the insulating layer 34, an insulating layer 92 composed of a transparent nonconductor film is formed, and the negative photoresist 91 is coated. After the negative photoresist 91 is developed, a portion of the insulating layer 92 is etched so that portions or the overall portions of the formed electrodes 38 and 39 are exposed. After that, the negative photoresist 91 which is present on the surface of the groove is removed to thereby form the insulating layer 92.

According to the flip chip light emitting diode and the method of manufacturing the same, predetermined regions of the grown active layer and p-type nitride semiconductor layer positioned between the mesas are etched, a plurality of regions of the n-type nitride semiconductor layer are exposed outside to form the plurality of grooves, and the insulating layer is formed on the surface of the groove to thereby induce the flow of current to the center portion. Further, the plurality of grooves are formed so that intervals between the grooves are designed to be gradually narrowed as they approach the n-type electrode, thereby reducing the cross-section of the current path. As a result, a large amount of current, which has been concentrated toward the n-type electrode in the related art, can flow into the center of the light emitting section, which makes it possible to obtain a current-spreading effect.

While the present invention has been described with reference to exemplary embodiments thereof, it will be understood by those skilled in the art that various changes and modifications in form and detail may be made therein without departing from the scope of the present invention as defined by the following claims.

According to the flip chip light emitting diode and the method of manufacturing the same, predetermined regions between the mesas as well as the mesas are etched to form the plurality of grooves, and the insulating layer is formed thereon, which makes it possible to induce the flow of current to the center of the light emitting section.

Furthermore, the plurality of grooves are formed so that intervals between the grooves are designed to be gradually narrowed as they approach the n-type electrode, thereby reducing the cross-section of the current path. As a result, a large amount of current, concentrated toward the n-type electrode, can flow into the center of the light emitting section, which makes it possible to obtain a current-spreading effect.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A method of manufacturing a flip chip light emitting diode comprising:
sequentially forming an n-type nitride semiconductor layer, an active layer, and a p-type nitride semiconductor layer on an optically-transparent substrate;
etching predetermined regions of the active layer and p-type nitride semiconductor layer and exposing a plurality of regions of the n-type nitride semiconductor layer so as to form a plurality of mesas;
etching predetermined regions of the active layer and p-type nitride semiconductor layer positioned between the formed mesas and exposing the plurality of regions of the n-type nitride semiconductor layer so as to form a plurality of grooves;
forming an insulating layer on the surface of the groove;
forming a p-type electrode across the insulating layer formed on the upper portion of the p-type nitride semiconductor layer and the surface of the groove; and
forming an n-type electrode on the formed mesa.

2. The method of manufacturing a flip chip light emitting diode according to claim 1, wherein, in forming the mesas or forming the grooves, etching is performed by an RIE method.

3. The method of manufacturing a flip chip light emitting diode according to claim 1, wherein, in forming the mesas or forming the grooves, the predetermined regions of the active layer and p-type nitride semiconductor layer are etched.

4. The method of manufacturing a flip chip light emitting diode according to claim 1, wherein, in forming the grooves, etching is performed so that the width of the groove corresponds to the range of 1 to 50 μm.

5. The method of manufacturing a flip chip light emitting diode according to claim 1, wherein, in forming the grooves, etching is performed so that intervals between the plurality of grooves are reduced as the intervals approach the mesa.

6. The method of manufacturing a flip chip light emitting diode according to claim 1, wherein, in forming the grooves, etching is performed so that an angle between the bottom and side surfaces of the groove is in the range of 90° to 165°.

7. The method of manufacturing a flip chip light emitting diode according to claim 1, wherein, in forming the p-type electrode, p-type ohmic metal, barrier metal, and bonding metal are sequentially laminated.

8. The method of manufacturing a flip chip light emitting diode according to claim 1, wherein, in forming the n-type electrode, n-type ohmic metal is laminated.

9. A flip chip light emitting diode comprising:
an optically-transparent substrate;
a light emitting structure that is formed by sequentially forming an n-type nitride semiconductor layer, an active layer, and a p-type nitride semiconductor layer on the substrate, the light emitting structure including:
a plurality of mesas that are formed by exposing a plurality of regions of the n-type nitride semiconductor layer so that the regions have a predetermined width; and
a plurality of grooves that are formed by exposing a plurality of regions of the n-type nitride semiconductor layer positioned between the mesas so that the regions have a predetermined width;
a groove insulating layer that is formed across the surface of the groove of the light emitting structure;
a p-type electrode that is formed across the insulting layer formed on the upper portion of the p-type nitride semiconductor layer and the surface of the groove in the light emitting structure; and
an n-type electrode that is formed on the plurality of mesas of the light emitting structure.

10. The flip chip light emitting diode according to claim 9, wherein the light emitting structure is formed by the reactive ion etching (RIE) of the active layer and p-type nitride semiconductor layer.

11. The flip chip light emitting diode according to claim 9, wherein the width of the groove positioned in the light emitting structure is in the range of 1 to 50 μm.

12. The flip chip light emitting diode according to claim 9, wherein the plurality of grooves formed in the light emitting structure are formed so that the intervals between the grooves are reduced as the intervals approach the mesa on which the n-type electrode is formed.

13. The flip chip light emitting diode according to claim 9, wherein the plurality of grooves formed in the light emitting structure are formed so that an angle between the bottom and side surfaces of the groove is in the range of 90° to 165°.

14. The flip chip light emitting diode according to claim 9, wherein the p-type electrode is formed by sequentially laminating p-type ohmic metal, barrier metal, and bonding metal.

15. The flip chip light emitting diode according to claim 9, wherein the n-type electrode is formed by laminating n-type ohmic metal.
